(19) United States
(12) Patent Application Publication
(10) Pub. No.: US 2025/0284191 A1
(43) Pub. Date: Sep. 11, 2025

(54) DEEP LEARNING MODELS FOR DETERMINING MASK DESIGNS ASSOCIATED WITH SEMICONDUCTOR MANUFACTURING

(71) Applicant: ASML NETHERLANDS B.V., Veldhoven (NL)

(72) Inventors: Markus Gerardus Martinus Maria VAN KRAAIJ, Eindhoven (NL); Scott Anderson MIDDLEBROOKS, Duizel (NL); Maxim PISARENCO, Son en Breugel (NL); Alexandru ONOSE, Eindhoven (NL); Robert Elliott BOONE, San Jose, CA (US); Yen-Wen LU, Saratoga, CA (US)

(73) Assignee: ASML NETHERLANDS B.V., Veldhoven (NL)

(21) Appl. No.: 18/863,693

(22) PCT Filed: Jul. 14, 2023
(86) PCT No.: PCT/EP2023/069734

§ 371 Date: Nov. 7, 2024

Related U.S. Application Data
(60) Provisional application No. 63/390,359, filed on Jul. 19, 2022.

(51) Int. Cl. G03F 1/36; G06N 3/094

(52) U.S. Cl. CPC G03F 1/36; G06N 3/094

(57) ABSTRACT

A method of determining a mask design, the method includes generating a continuous multimodal representation of a probability distribution of a target design in at least a portion of a latent space. The latent space includes a distribution of feature variants that can be used to generate mask designs based on the target design. The method includes selecting a variant from the continuous multimodal representation in the latent space. The variant includes a latent space representation of one or more features to be used to determine the mask design. The method includes determining the mask design based on the target design and the variant.

### CROSS-REFERENCE TO RELATED APPLICATIONS

This application claims priority of U.S. application 63/390,359 which was filed on Jul. 19, 2022 and which is incorporated herein in its entirety by reference.

### TECHNICAL FIELD

The present disclosure relates generally to determining lithography mask designs associated with semiconductor manufacturing.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from an illumination source, creating individual functional elements having dimensions well below 100 nm.

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”-generally the smallest feature size printed- and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, source mask optimization (SMO), or other methods generally defined as “resolution enhancement techniques” (RET).

### SUMMARY

In generating training data from target designs for training prediction models to predict mask designs for a semiconductor manufacturing process, similar target design patterns may result in different predicted mask designs, and thus different training data (e.g., even though similar target design patterns may be almost exactly the same). The inconsistent training data causes typical machine learning models to predict averaged mask design features, which results in ambiguity in feature extraction and often leads to varying defect prediction for a given semiconductor manufacturing process.

The present disclosure describes a model that learns a continuous multimodal distribution of mask features that result in valid wafer imaging, and selects a (best) variant from the continuous multimodal distribution. The variant comprises a latent space representation of one or more features to be used to determine the mask design. The model determines a mask design based on a target design and the variant. This provides consistent training data, which reduces ambiguity in feature extraction, and enhances defect prediction for a given semiconductor manufacturing process, among other advantages.

According to an embodiment, there is provided a method of determining a mask design. The method comprises generating a continuous multimodal representation of a probability distribution of a target design in at least a portion of a latent space. The latent space comprises a distribution of feature variants that can be used to generate mask designs based on the target design. The method comprises selecting a variant from the continuous multimodal representation in the latent space. The variant comprises a latent space representation of one or more features to be used to determine the mask design. The method comprises determining the mask design based on the target design and the variant.

In some embodiments, selecting the variant comprises selecting a mode from the multimodal representation of the probability distribution, and sampling the variant from the selected mode.

In some embodiments, the generating, the selecting, and the determining are performed by an encoder structure and a generative structure with a conditional mapping sub-model.

In some embodiments, the encoder structure and the generative structure form a U-net type deep learning model.

In some embodiments, the deep learning model with the conditional mapping sub-model comprises a first neural network block configured for generating the continuous multimodal representation of the probability distribution of the target design in the latent space, a second neural network block configured for selecting the variant during training, and a third neural network block configured for determining the mask design based on the target design and the variant.

In some embodiments, the first, second, and third neural network blocks are trained jointly.

In some embodiments, the second neural network block is trained to generate the distribution of feature variants that exist in input sub resolution assist feature (SRAF) and/or optical proximity correction (OPC) data.

In some embodiments, during training, selected variants are used as ground truth to train the third neural network block to generate the mask design from an input target design and a mode selection choice given a selected variant.

In some embodiments, the variant comprises information content from a mask domain or propagation of that information from the second neural network block to the latent space. In some embodiments, the variant comprises information content from an OPC and/or SRAF domain or propagation of that information from the second neural network block to the latent space. A mask, OPC, and/or SRAF domain may be and/or include data, calculations, manufacturing operations, and/or other information associated with a mask, OPC, and/or an SRAF.

In some embodiments, the method further comprises training the first, second, and third neural network blocks by classifying output mask designs as fake or genuine with an adversarial training sub-model such that, after training, outputs from the third neural network block are indistinguishable by the adversarial sub-model from real reference data.

In some embodiments, the method further comprises applying additional regularization/loss cost during the training of the first, second, and third neural network blocks.

In some embodiments, application of the regularization/loss cost comprises application of cost terms that penalize an amount of jagged edges in the determined mask design, reweighting of cost terms that penalize the amount of jagged edges, application of a cost term that places priority of binary pixel values in an image associated with the determined mask design, application of a fixed selection choice for a selection of a best mask design, and/or applying regularization on difference between two versions of the mask design.

In some embodiments, the target design comprises an intended wafer pattern, and/or intermediate data associated with the intended wafer pattern including continuous transmission mask (CTM) data, a CTM image, and/or an intermediate mask design.

In some embodiments, determining the mask design based on the target design and the variant comprises (1) mapping the target design, the CTM data, and/or the CTM image, and/or an intermediate mask design, to the mask design, and/or (2) mapping the target design to the CTM data and/or the CTM image.

In some embodiments, the latent space models the distribution of feature variants that can be used to generate mask designs via variation Bayes inference techniques.

In some embodiments, a feature comprises a shape or structure associated with a target and/or a reticle design for a semiconductor device.

In some embodiments, the method further comprises performing forward consistency sub-modelling configured to ensure the determined mask design will create a desired semiconductor wafer structures that correspond to the target design.

In some embodiments, the forward consistency sub-modelling is performed by a fixed physical model and/or a parametric model that approximates physics of a semiconductor manufacturing process.

In some embodiments, determining the mask design comprises determining sub resolution assist feature (SRAF) and/or optical proximity correction (OPC) data for the mask design.

In some embodiments, the SRAF data and the OPC data are determined as separate contributions.

In some embodiments, the target design is a target substrate design for a semiconductor wafer.

In some embodiments, the determined mask design comprises an image.

In some embodiments, the method further comprises sampling a resulting conditional latent space by generating multiple selection options; and evaluating process window key performance indicators for resulting mask designs such that a most robust mask that a pretrained model can produce is determined.

According to another embodiment, there is provided a method of determining a semiconductor mask design with a model that learns a multimodal distribution of mask features, and selects variants that result in valid semiconductor wafer imaging. The method comprises generating, with a first neural network block of the model, a continuous multimodal representation of a probability distribution of a wafer target design in at least a portion of a latent space. The latent space comprises a distribution of feature variants that can be used to generate mask designs based on the target design. The method comprises selecting, with a second neural network block of the model and during training of the model, a variant from the continuous multimodal representation in the latent space. The variant comprises a latent space representation of one or more features to be used to determine the mask design. The selecting comprises selecting a mode from the multimodal representation of the probability distribution, and sampling the variant from the selected mode. The method comprises determining, with a third neural network block of the model, the mask design based on the target design and the variant. The model may be a U-net type deep learning model with a conditional mapping sub-model, for example.

According to another embodiment, there is provided a non-transitory computer readable medium having instructions thereon, the instructions when executed by a computer causing the computer to perform any of the operations of the methods described above.

According to another embodiment, there is provided a system comprising one or more processors configured to perform any of the operations of the methods described above.

Other advantages of the embodiments of the present disclosure will become apparent from the following description taken in conjunction with the accompanying drawings, which set forth, by way of illustration and example, certain example embodiments.

### BRIEF DESCRIPTION OF THE DRAWINGS

The accompanying drawings, which are incorporated in and constitute a part of the specification, illustrate one or more embodiments and, together with the description, explain these embodiments. Embodiments will now be described, by way of example only, with reference to the accompanying schematic drawings in which corresponding reference symbols indicate corresponding parts, and in which:

FIG. 1 is a schematic diagram of a lithographic projection apparatus, according to an embodiment.

FIG. 2 depicts a schematic overview of a lithographic cell, according to an embodiment.

FIG. 3 depicts a schematic representation of holistic lithography, representing a cooperation between three technologies to optimize semiconductor manufacturing, according to an embodiment.

FIG. 4 illustrates an exemplary flow chart for simulating lithography, according to an embodiment.

FIG. 5 illustrates encoder-decoder architecture, according to an embodiment.

FIG. 6 illustrates encoder-decoder architecture within a neural network, according to an embodiment.

FIG. 7 illustrates a summary of operations of one embodiment of a present method for determining a mask design, according to an embodiment.

FIG. 8 illustrates a generalized high level representation of a model associated with some of the ideas described herein, comprising an encoder structure, a generative structure, and a conditional mapping sub-model, according to an embodiment.

FIG. 9 illustrates a more specific representation of the model comprising an encoder structure, a generative structure, and a conditional mapping sub-model, according to an embodiment.

FIG. 10 illustrates an adversarial sub-model that may be included in and/or used to train the model, according to an embodiment.

FIG. 11 illustrates a forward consistency sub-model that may be included in and/or used to train the model, according to an embodiment.

FIG. 12 shows an embodiment of the model where optical proximity correction (OPC) and sub-resolution assist features (SRAF) contributions are treated separately, and then combined to generate a mask design, according to an embodiment.

FIG. 13 schematically illustrates iterations involved in finding joint solutions to a training optimization associated with the model, according to an embodiment.

FIG. 14 illustrates equations used for training the model, according to an embodiment.

FIG. 15 illustrates an example of using a trained model to infer (or otherwise determine) a mask design (with OPC/SRAF features), according to an embodiment.

FIG. 16 illustrates two different possible example options of the model reconfigured for training a fixed latent selection to achieve a target performance level with respect to predefined key performance indicators (KPIs) for a semiconductor manufacturing process, according to an embodiment.

FIG. 17 illustrates an example embodiment of the model configured to account for lithography scanner focus perturbations, according to an embodiment.

FIG. 18 is a diagram of an example computer system that may be used for one or more of the operations described herein, according to an embodiment.

### DETAILED DESCRIPTION

The design of lithography reticles involves finding a solution to an inverse problem: i.e., given a set of target features on a substrate such as a wafer, equivalent reticle features needed to accurately expose a pattern on the substrate must be determined. Traditionally, this inverse lithography task is solved as a series of optimization problems that find a best mask design under multiple requirements from a semiconductor manufacturing process (e.g., for the mask design itself, and also for process windows associated with forming various features in a substrate).

Often, the current approach to solve this inverse problem comprises a series of subtasks: a) a physics based model is used for characterizing the physical system (e.g., a scanner reticle optical model and a resist model); the physics based model is deployed as a forward model in an optimization task that aims to partially solve the inverse problem going from a target design to an intermediary continuous representation of a desired mask (e.g., a continuous transmission mask CTM); b) a deep learning model is constructed and trained to reproduce the outcome of the inverse problem, which after training allows for a fast evaluation of the appropriate CTMs; and c) a series of discretization and post-processing operations are performed to translate the resulting CTMs, from the physics based model or from the deep learning model, to an appropriate mask design (e.g., using optical proximity correction (OPC) and/or sub-resolution assist features (SRAF)) that satisfies criteria for manufacturability and the desired target design.

However, using the current approach, mapping from CTMs to SRAF/OPC features is unstable. For example, for small perturbations in CTMs, generated OPC/SRAF features in a mask design can be widely varied. Such differences are undesirable since they introduce unwanted variance and/or different features in generated mask designs, which makes eventual semiconductor manufacturing process control difficult. Additionally, this instability does not allow straightforward creation of machine learning models to automate and speed up mapping between CTMs and a target design since the models are trained using data which is unstable. Finally, the current approach does not directly incorporate performance criteria for resulting mask designs. This criteria is intrinsic to the discrete steps taken when the CTMs are mapped to the OPC/SRAF features, for example.

For example, in order to train a model, ground truth images are generated. Using the current approach, generating ground truth images results in vastly different output (SRAF+OPC) images given similar input (target) images (e.g., due to the instability described above). This variance in output images (from prior/classical/naïve prediction models-before the present models described herein) causes the model to learn an “average” of the output (SRAF+OPC) image, resulting in ambiguous and inappropriate mask designs, which may not image properly, or will not be manufacturable.

In contrast to the model(s) used in the current approach, a new deep learning model configured to solve the inverse mapping problem is described herein. This model can be built based on the concepts described below. The model is configured to learn a multimodal distribution of features of a mask that result in manufacturable target designs on a substrate such as a wafer. The model is composed of several sub-models, which are trained as a single monolithic model, as described below.

The new deep learning model is configured to accept the variance in the ground truth output (SRAF+OPC) and explicitly learn the distribution of the output (SRAF+OPC) images that can arise from similar inputs (target designs). This distribution (probability density function) can be modeled, for example via variational Bayes, in a lower-dimensional, real, and continuous latent-space. Given an input (target) image, samples from the latent-space probability density function will each generate their own mask variants. Each of these mask variants will be representative of the ground truth images that were used to train the network and will no longer be ambiguous. Since the latent-space is variational, parameters such as σ_ₚᵣᵢₒᵣ give information about how varied the output (SRAF+OPC) images are for this particular input (target). This information can also be utilized to guide training of the model.

Embodiments of the present disclosure are described in detail with reference to the drawings, which are provided as illustrative examples of the disclosure so as to enable those skilled in the art to practice the disclosure. The figures and examples below are not meant to limit the scope of the present disclosure to a single embodiment, but other embodiments are possible by way of interchange of some or all of the described or illustrated elements. Where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. The present disclosure encompasses present and future known equivalents to the known components referred to herein by way of illustration.

Although specific reference may be made in this text to the manufacture of ICs, it should be explicitly understood that the description herein has many other applications. For example, it may be employed in the manufacture of integrated optical systems, guidance and detection patterns for magnetic domain memories, liquid-crystal display (LCD) panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate,” and “target portion,” respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

A (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include or specify specific parameters, limits on ranges for parameters, or other information. One or more of the design rule limitations or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate. Besides the classic mask (transmissive or reflective; binary, phase-shifting, hybrid, etc.), examples of other such patterning devices include a programmable mirror array and a programmable LCD array.

As used herein, the term “patterning process” means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer).

As used herein, a “printed pattern” (or a pattern on a substrate) means the physical pattern on a substrate that was etched based on a target pattern. The printed pattern can include, for example, troughs, channels, depressions, edges, or other two and three dimensional features resulting from a lithography process.

As used herein, the term “calibrating” means to modify (e.g., improve or tune) or validate something, such as a model.

A patterning system may be a system comprising any or all of the components described herein, plus other components configured to performing any or all of the operations associated with these components. A patterning system may include a lithographic projection apparatus, a scanner, systems configured to apply or remove resist, etching systems, or other systems, for example.

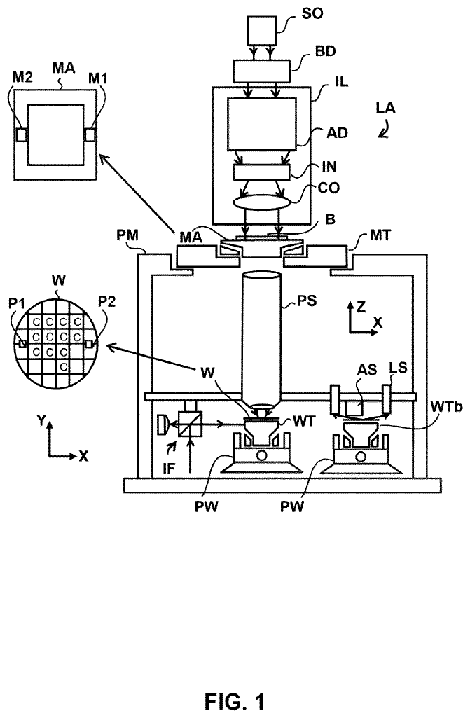

As an introduction, FIG. 1 is a schematic diagram of a lithographic projection apparatus LA, according to an embodiment. LA may be used to produce a patterned substrate (e.g., wafer) as described. The patterned substrate may be inspected/measured by an SEM according to the FOV lists as part of a semiconductor manufacturing process, for example.

Lithographic projection apparatus LA can include an illumination system IL, a first object table MT, a second object table WT, and a projection system PS. Illumination system IL, can condition a beam B of radiation. In this example, the illumination system also comprises a radiation source SO. First object table (e.g., a patterning device table) MT can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

LA can be transmissive (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer or inner radial extent (commonly referred to as σ-outer and σ-inner, respectively) of the intensity distribution in the beam. In addition, it will comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table MT. Having traversed patterning device MA, the beam B can pass through a lens, which focuses beam B onto target portion C of substrate W. With the aid of the second positioning means (and interferometric measuring means IF), the substrate table WT can be moved accurately, e.g., to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the tables MT, WT can be realized with the aid of a long-stroke module (coarse positioning) and a short-stroke module (fine positioning). However, in the case of a stepper (as opposed to a step-and-scan tool), patterning device table MT may be connected to a short stroke actuator, or may be fixed.

The depicted tool can be used in two different modes, step mode and scan mode. In step mode, patterning device table MT is kept stationary, and an entire patterning device image is projected in one operation (i.e., a single “flash”) onto a target portion C. Substrate table WT can be shifted in the x or y directions so that a different target portion C can be irradiated by beam B. In scan mode, the same scenario applies, except that a given target portion C is not exposed in a single “flash.” Instead, patterning device table MT is movable in a given direction (e.g., the “scan direction,” or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=1/4 or 1/5). In this manner, a large target portion C can be exposed, without having to compromise on resolution.

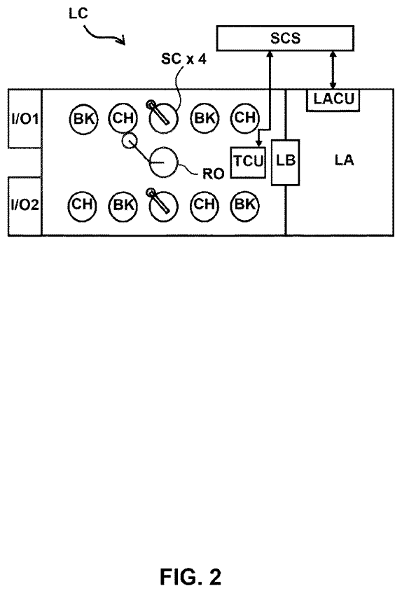

FIG. 2 depicts a schematic overview of a lithographic cell LC. As shown in FIG. 2, a lithographic projection apparatus (shown in FIG. 1 and illustrated as lithographic apparatus LA in FIG. 2) may form part of lithographic cell LC, also sometimes referred to as a lithocell or (litho) cluster, which often also includes apparatus to perform pre- and post-exposure processes on a substrate W (FIG. 1). Conventionally, these include spin coaters SC configured to deposit resist layers, developers to develop exposed resist, chill plates CH and bake plates BK, e.g., for conditioning the temperature of substrates W, e.g., for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g., via lithography control unit LACU.

In order for the substrates W (FIG. 1) exposed by the lithographic apparatus LA to be exposed correctly and consistently, it is desirable to inspect substrates to measure properties of patterned structures, such as feature edge placement, overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties using an actual substrate (e.g., a charged particle-SEM-image of a wafer pattern) or an image of an actual substrate, on a latent image (image in a resist layer after the exposure), on a semi-latent image (image in a resist layer after a post-exposure bake step PEB), on a developed resist image (in which the exposed or unexposed parts of the resist have been removed), on an etched image (after a pattern transfer step such as etching), or in other ways.

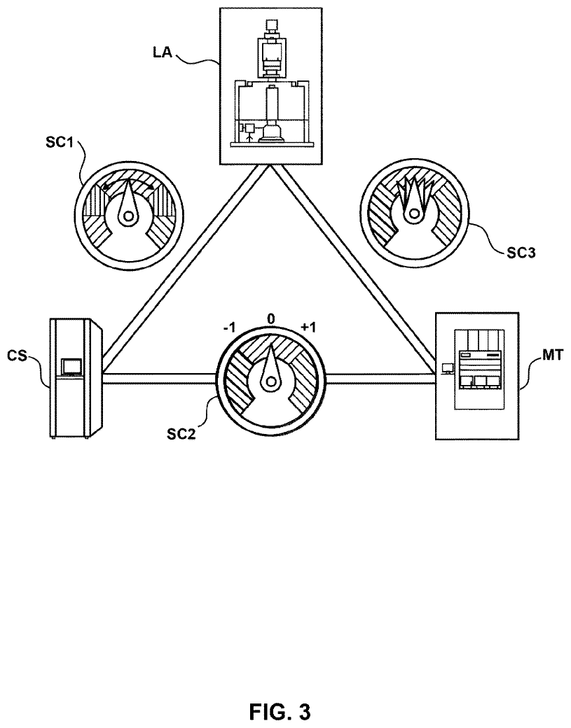

FIG. 3 depicts a schematic representation of holistic lithography, representing a cooperation between three technologies to optimize semiconductor manufacturing. Typically, the patterning process in lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is lithographic apparatus LA which is (virtually) connected to a metrology apparatus (e.g., a metrology tool) MT (a second system), and to a computer system CS (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CS may use (part of) a design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CS may also be used to detect where within the process window the lithographic apparatus LA is currently operating (e.g., using input from the metrology tool MT) to predict whether defects may be present due to e.g., sub-optimal processing (depicted in FIG. 3 by the arrow pointing “0” in the second scale SC2).

The metrology apparatus (tool) MT may provide input to the computer system CS to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

In lithographic processes, it is desirable to make frequent measurements of the structures created, e.g., for process control and verification. Tools to make such measurements include metrology tool (apparatus) MT. Different types of metrology tools MT for making such measurements are known, including scanning electron microscopes (SEM) or various forms of scatterometer metrology tools MT. In some embodiments, metrology tools MT are or include an SEM.

In some embodiments, metrology tools MT are or include a spectroscopic scatterometer, an ellipsometric scatterometer, or other light based tools. A spectroscopic scatterometer may be configured such that the radiation emitted by a radiation source is directed onto target features of a substrate and the reflected or scattered radiation from the target is directed to a spectrometer detector, which measures a spectrum (i.e., a measurement of intensity as a function of wavelength) of the specular reflected radiation. From this data, the structure or profile of the target giving rise to the detected spectrum may be reconstructed, e.g., by Rigorous Coupled Wave Analysis and non-linear regression or by comparison with a library of simulated spectra. An ellipsometric scatterometer allows for determining parameters of a lithographic process by measuring scattered radiation for each polarization states. Such a metrology tool (MT) emits polarized light (such as linear, circular, or elliptic) by using, for example, appropriate polarization filters in the illumination section of the metrology apparatus. A source suitable for the metrology apparatus may provide polarized radiation as well.

It is often desirable to be able to computationally determine how a patterning process would produce a desired pattern on a substrate. Thus, simulations may be provided to simulate one or more parts of the process. For example, it is desirable to be able to simulate the lithography process of transferring the patterning device pattern onto a resist layer of a substrate as well as the yielded pattern in that resist layer after development of the resist.

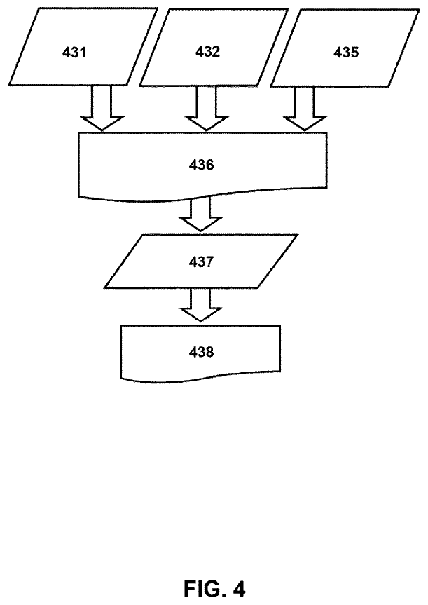

FIG. 4 illustrates an exemplary flow chart for simulating lithography in a lithographic projection apparatus. An illumination model 431 represents optical characteristics of the illumination. A projection optics model 432 represents optical characteristics of the projection optics. A design layout model 435 represents optical characteristics (including changes to the radiation intensity distribution and/or the phase distribution caused by a given design layout) of a design layout, which is the representation of an arrangement of features on or formed by a patterning device. An aerial image 436 can be simulated using the illumination model 431, the projection optics model 432, and the design layout model 435. A resist image 438 can be simulated from the aerial image 436 using a resist model 437. Mask images, such as a CTM mask and/or other masks, may also be simulated (e.g., by the design layout model 435 and/or other models), for example. Simulation of lithography can, for example, predict contours and/or CDs in the resist image.

More specifically, illumination model 431 can represent the optical characteristics of the illumination that include, but are not limited to, NA-sigma (σ) settings as well as any particular illumination shape (e.g., off-axis illumination such as annular, quadrupole, dipole, etc.). The projection optics model 432 can represent the optical characteristics of the of the projection optics, including, for example, aberration, distortion, a refractive index, a physical size or dimension, etc. The design layout model 435 can also represent one or more physical properties of a physical patterning device. Optical properties associated with the lithographic projection apparatus (e.g., properties of the illumination, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the illumination and the projection optics (hence design layout model 435).

The resist model 437 can be used to calculate the resist image from the aerial image. The resist model is typically related to properties of the resist layer (e.g., effects of chemical processes which occur during exposure, post-exposure bake and/or development).

The model can be used to accurately predict, for example, edge placements, aerial image intensity slopes, sub resolution assist features (SRAF), and/or CDs, which can then be compared against an intended or target design. The intended design is defined as a pre-OPC design layout which can be provided in a standardized digital file format such as GDSII, OASIS or another file format.

For example, the simulation and modeling can be used to configure one or more features of the patterning device pattern (e.g., performing optical proximity correction), one or more features of the illumination (e.g., changing one or more characteristics of a spatial/angular intensity distribution of the illumination, such as change a shape), and/or one or more features of the projection optics (e.g., numerical aperture, etc.). Such configuration can be referred to as, respectively, mask optimization, source optimization, and projection optimization. Such optimization can be performed on their own, or combined in different combinations. One such example is source-mask optimization (SMO), which involves the configuring of one or more features of the patterning device pattern together with one or more features of the illumination. The optimization techniques may focus on one or more of the clips. The optimizations may use the machine learning model described herein to predict values of various parameters (including images, etc.).

In some embodiments, an optimization process of a system may use a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as dose and focus, for example.

In some embodiments, illumination model 431, projection optics model 432, design layout model 435, resist model 437, and/or other models associated with and/or included in an integrated circuit manufacturing process may be an empirical model that performs the operations of the method described herein. The empirical model may predict outputs based on correlations between various inputs (e.g., one or more characteristics of a mask or wafer image, one or more characteristics of a design layout, one or more characteristics of the patterning device, one or more characteristics of the illumination used in the lithographic process such as the wavelength, etc.).

As an example, the empirical model may be a machine learning model and/or any other parameterized model. In the paragraphs above, certain non-machine learning model computational lithography physical models were described. Machine learning models may be different in that they by-pass all or some of the physical models (e.g., the optical model described above). In some embodiments, a machine learning model (for example) may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

The one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be freer flowing, with connections interacting in a more chaotic and complex fashion. In some embodiments, the intermediate layers of the one or more neural networks include one or more convolutional layers, one or more recurrent layers, and/or other layers.

The one or more neural networks may be trained (i.e., whose parameters are determined) using a set of training data (e.g., ground truths). The training data may include a set of training samples. Each sample may be a pair comprising an input object (typically a vector, which may be called a feature vector) and a desired output value (also called the supervisory signal). A training algorithm analyzes the training data and adjusts the behavior of the neural network by adjusting the parameters (e.g., weights of one or more layers) of the neural network based on the training data. For example, given a set of N training samples of the form {(x₁, y₁), (x₂, y₂), . . . , (x_{N}, y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object (e.g., a wafer design as in the example above, a clip, etc.). The vector space associated with these vectors is often called the feature or latent space. After training, the neural network may be used for making predictions using new samples.

As described herein, embodiments of the present disclosure include model(s) include one or more parameterized models (e.g., machine learning models such as a neural network) that use an encoder-decoder architecture, and/or other models. In the middle (e.g., middle layers) of the model (e.g., a neural network), the present model formulates a low-dimensional encoding (e.g., in a latent space) that encapsulates information in an input to the model. The present model(s) leverage the low dimensionality and compactness of the latent space to make parameter estimations and/or predictions.

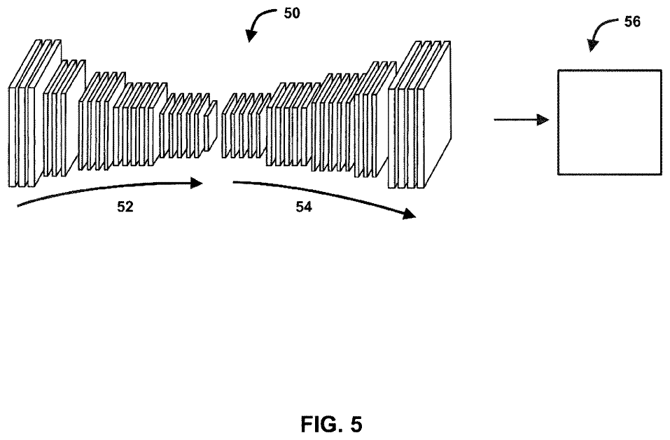

By way of a non-limiting example, FIG. 5 illustrates general encoder-decoder architecture 50. Encoder-decoder architecture 50 has an encoding portion 52 (an encoder) and a decoding portion 54 (a decoder). In the example shown in FIG. 5, encoder-decoder architecture 50 may output predicted images 56 and/or other outputs, for example.

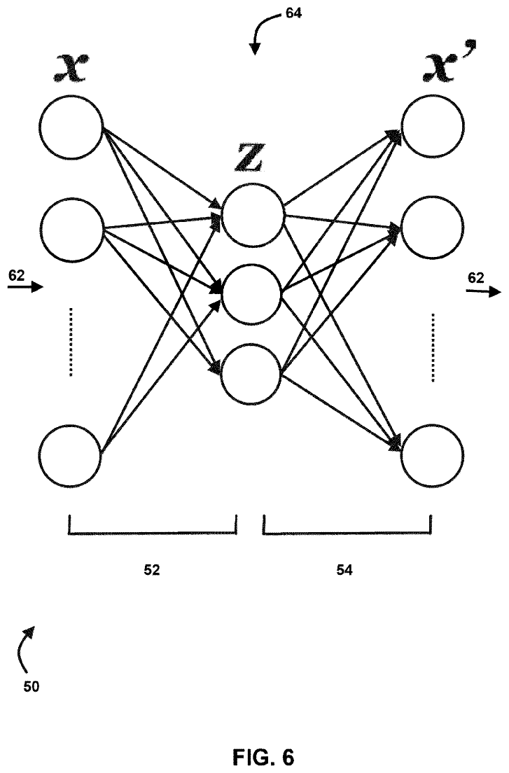

By way of another non-limiting example, FIG. 6 illustrates encoder-decoder architecture 50 within a neural network 62. Encoder-decoder architecture 50 includes encoding portion 52 and decoding portion 54. In FIG. 6, x represents encoder input (e.g., an input image or other data) and x′ represents decoder output (e.g., a predicted output image and/or other data). In FIG. 6, z represents the latent space 64 and/or a low dimensional encoding (tensor/vector). In some embodiments, z is or is related to a latent variable.

In some embodiments, the low dimensional encoding z represents one or more features of an input. The one or more encoded features of the input may be considered key or critical features of the input. Encoded features may be considered key or critical features of an input because they are more predictive than other features of a desired output and/or have other characteristics, for example. The one or more encoded features (dimensions) represented in the low dimensional encoding may be predetermined (e.g., by a programmer at the creation of the present modular autoencoder model), determined by prior layers of a neural network, adjusted by a user via a user interface associated with a system described herein, and/or may be determined in by other methods. In some embodiments, a quantity of encoded features (dimensions) represented by the low dimensional encoding may be predetermined (e.g., by the programmer at the creation of the present modular autoencoder model), determined based on output from prior layers of the neural network, adjusted by the user via the user interface associated with a system described herein, and/or determined by other methods.

It should be noted that even though a machine learning model, a neural network, and/or encoder-decoder architecture are mentioned throughout this specification, a machine learning model, a neural network, and encoder-decoder architecture are just examples, and the operations described herein may be applied to different parameterized models.

As described above, process information (e.g., images, measurements, process parameters, metrology metrics, etc.) may be used to guide various manufacturing operations. Utilizing the lower dimensionality of a latent space to predict and/or otherwise determine the process information may be faster, more efficient, require fewer computing resources, and/or have other advantages over prior methods for determining process information.

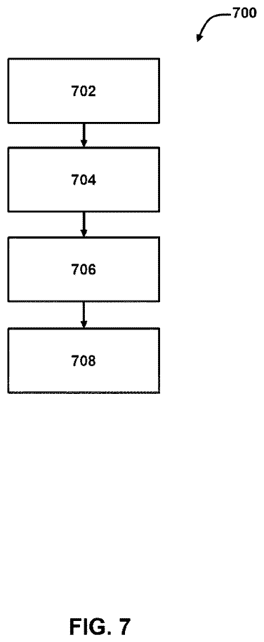

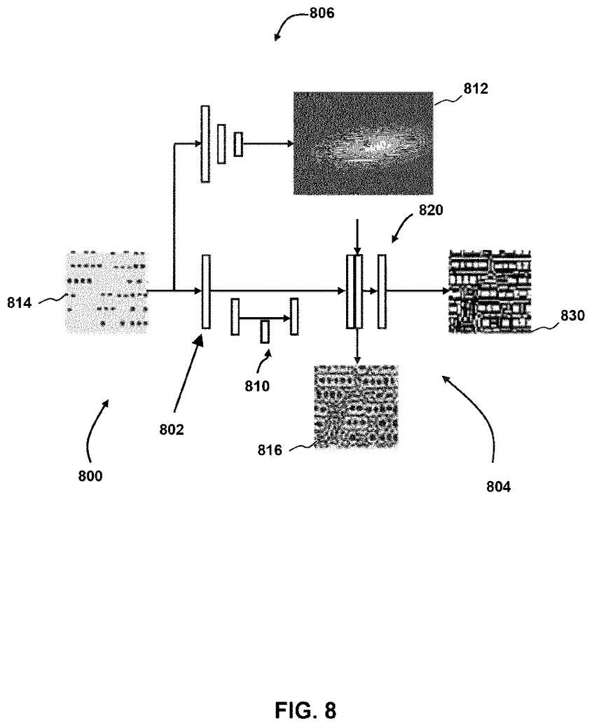

FIG. 7 illustrates a summary 700 of operations of one embodiment of a present method for determining a mask design. Summary 700 is an overview of training and/or inference operations described herein. At an operation 702, a continuous multimodal representation of a probability distribution of a target design is generated in at least a portion of a latent space. At an operation 704 a feature variant is selected from the continuous multimodal representation in the latent space. At an operation 706, the mask design is determined based on the target design and the variant, and/or other information. Operation 708 may comprise one or more steps performed to enhance the mask design determination. A brief overview of these operations is presented in the paragraphs that immediately follow, and then in depth explanations of each operation are provided in the discussion of FIGS. 8-17 below.

In some embodiments, one or more operations described in summary 700 may be performed simultaneously and/or sequentially. For example, during training operations 704, 706, and 708 may be applied together (or partially since some elements of 708 may be omitted). In some embodiments, one or more of these operations may be performed iteratively during training and/or during inference. The description below is an example of a sequence of steps of joint operations for one training iteration or for one inference step, for example. For training, for example, operations 702 and 708 are interlinked, and are performed iteratively. At inference however, the regularization from operation 708 (described below) may not be used, but a forward model may still be used (as described below).

In some embodiments, a non-transitory computer readable medium stores instructions which, when executed by a computer, cause the computer to execute one or more of operations 702-708, or other operations. Operations 702-708 are intended to be illustrative. In some embodiments, these operations may be accomplished with one or more additional operations not described, or without one or more of the operations discussed. For example, in some embodiments, operation 708 may be eliminated. Additionally, the order in which operations 702-708 are illustrated in FIG. 7 and described herein is not intended to be limiting. For example, some or all of operations 702-708 may be performed simultaneously.

The generating, the selecting, and the determining (e.g., operation 702, operation 704, and operation 706) are performed by an electronic model comprising an encoder structure and a generative structure (e.g., a decoder) with a conditional mapping sub-model. In some embodiments, as described herein, the model is a machine learning model. In some embodiments, the model comprises encoder-decoder architecture. In an embodiment, the encoder-decoder architecture comprises variational encoder-decoder architecture, and operation 702 and/or other operations comprise training the variational encoder-decoder architecture with a probabilistic latent space, which generates realizations in an output space. The latent space comprises low dimensional encodings and/or other information (as described herein). A latent space is probabilistic if it is formed by sampling from a distribution (such as Gaussian) given the parameters of the distribution (such as mu and sigma) computed by the encoder.

In some embodiments, the encoder structure and the generative structure form a U-net type deep learning model. The U-net type deep learning model with the conditional mapping sub-model comprises a first neural network block configured for generating the continuous multimodal representation of the probability distribution of the target design in the latent space, a second neural network block configured for selecting the variant during training, and a third neural network block configured for determining the mask design based on the target design and the variant. In some embodiments, the latent space models the distribution of feature variants that can be used to generate mask designs via variation Bayes inference techniques, for example.

As described above, at operation 702, a continuous multimodal representation of a probability distribution of a target design is generated in at least a portion of a latent space. In some embodiments, the target design is a target substrate design for a semiconductor wafer. In some embodiments, the target design comprises an intended wafer pattern, a .GDS file, a target layout, and/or intermediate data associated with the intended wafer pattern. In some embodiments, the target design may be associated with other data including continuous transmission mask (CTM) data (a CTM comprises a desired mask image), a CTM image, an intermediate mask design, and/or other data. The latent space comprises a distribution of feature variants that can be used to generate mask designs based on the target design. A mask feature (as opposed to an encoding feature described above) may comprise a shape or structure associated with a target and/or a reticle design for a semiconductor device, for example.

In some embodiments, operation 702 comprises training the first, second, and third neural network blocks jointly (e.g., before using the model for inference operations). In some embodiments, the second neural network block is trained to generate the distribution of feature variants that exist in input sub resolution assist feature (SRAF) and/or optical proximity correction (OPC) data, for example. During training, selected variants are used as ground truth to train the third neural network block to generate the mask design from an input target design and a mode selection choice given a selected variant.

At operation 704, a variant is selected from the continuous multimodal representation in the latent space. The variant comprises a latent space representation of one or more features to be used to determine the mask design. Selecting the variant comprises selecting a mode from the multimodal representation of the probability distribution, and sampling the variant from the selected mode. In some embodiments, the variant comprises information content from a mask domain or propagation of that information from the second neural network block to the latent space. In some embodiments, the variant comprises information content from an OPC and/or SRAF domain or propagation of that information from the second neural network block to the latent space. A mask, OPC, and/or SRAF domain may be and/or include data, calculations, manufacturing operations, and/or other information associated with a mask, OPC, and/or an SRAF.

At operation 706, the mask design is determined based on the target design and the variant, and/or other information. In some embodiments, the determined mask design comprises an image. In some embodiments, determining the mask design based on the target design and the variant comprises (1) mapping the target design, the CTM data, and/or the CTM image to the mask design, and/or (2) mapping the target design to the CTM data and/or the CTM image. In some embodiments, determining the mask design comprises determining sub resolution assist feature (SRAF) and/or optical proximity correction (OPC) data for a mask design. In some embodiments, the SRAF data and the OPC data are determined as separate contributions.

Operation 708 may comprise one or more steps performed to enhance the mask design determination. In some embodiments, operation 708 comprises training (or re-training) the first, second, and third neural network blocks by classifying output mask designs as fake or genuine with an adversarial training sub-model such that, after training, outputs from the third neural network block are indistinguishable by the adversarial sub-model from real reference data. In some embodiments, operation 708 comprises applying additional regularization/loss cost during the training of the first, second, and third neural network blocks. Application of the regularization/loss cost comprises application of cost terms that penalize an amount of jagged edges in the determined mask design, reweighting of cost terms that penalize the amount of jagged edges, application of a cost term that places priority of binary pixel values in an image associated with the determined mask design, application of a fixed selection choice for a selection of a best mask design, and/or applying regularization on difference between two versions of the mask design.

In some embodiments, operation 708 comprises performing forward consistency sub-modelling configured to ensure the determined mask design will create a desired semiconductor wafer structures that correspond to the target design. In some embodiments, the forward consistency sub-modelling is performed by a fixed physical model and/or a parametric model that approximates physics of a semiconductor manufacturing process. In some embodiments, operation 708 comprises sampling a resulting conditional latent space by generating multiple selection options; and evaluating process window key performance indicators for resulting mask designs such that a most robust mask that a pretrained model can produce is determined.

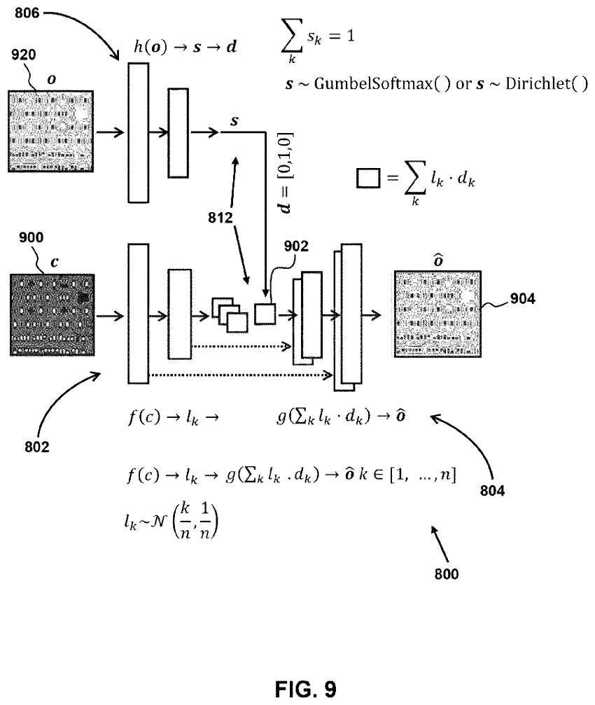

By way of a non-limiting example, FIG. 8 illustrates a generalized high level representation of a model 800 associated with some of the ideas described herein, comprising an encoder structure, a generative structure, and a conditional mapping sub-model. FIG. 8 illustrates a generalized representation of model 800 comprising an encoder structure 802, a generative structure 804, and a conditional mapping sub-model 806. Model 800 generates a uni-modal distribution. Model 800 assumes that both target data and mask data can be mapped to a common distribution, however this embodiment is not configured to create the multimodal distribution (a resulting distribution will be a common distribution of the features associated with a target and a mask and not the distribution of the mask features). Further details related to the high level concepts presented in FIG. 8 are shown and described in FIG. 9+ below.

Encoder structure 802 and generative structure 804 form a U-net type deep learning model 810. A real and continuous variational low-dimensional latent space 812 is included as part of model 800. During inference, an input image 814 (target design) is projected simultaneously to a CTM like image 816, as well as encoded into the latent-space, which models (via variational Bayes) the distribution of mask variants that can be generated. Given an input image 814, samples from a latent space probability density function will each generate their own mask variant 820. Since latent space 812 is variational, parameters such as σₚᵣᵢₒᵣ give information about how varied output (SRAF+OPC) images 830 are for this particular input image 814.

A minimal training set for model 800 could comprise target designs and corresponding mask designs (e.g., more than one per target design). However, if CTMs are also available, the CTMs can be used as secondary ground truth during training in order to enforce physical interpretability of the U-net output. (Note that generalized model 800 can also be applied to freeform SRAF+OPC.)

FIG. 9 illustrates a more specific representation of model 800 comprising encoder structure 802, generative structure 804, and conditional mapping sub-model 806. Conditional mapping sub-model 806 is conditional on existing features in given OPC/SRAF data 920, and infers OPC/SRAF features from input CTMs or alternatively directly from input target information. In this example, encoded features are learned from the OPC/SRAF data. Data 920 data and data related to a mask design 904 (described below) are be associated with the same sample to produce a consistent mapping (one is the real sample the other it the output approximation).

Conditional mapping sub-model 806 is used to generate latent space 812 so that it models a discrete categorical distribution. Here, “s” is the probability distribution of the given features/variants that are sampled to generate a categorical sample with a 1-hot encoding represented by “d”. This can be appreciated and made tractable, for example, using a GumbelSoftmax approach. The conditional construct shown in FIG. 9 facilitates training model 800 so that it is aware of a choice made in reference data for a given feature. This choice may be encoded via a discrete categorical one-hot encoding d, as shown FIG. 9. In FIG. 9, d conditions or otherwise selects the version of features to be inferred in an output image (e.g., mask design 904).

As shown in FIG. 9, encoder structure 802 and generative structure 804 again form a U-net type deep learning model. The U-net type deep learning model with conditional mapping sub-model 806 comprises a first neural network block (encoder structure 802) configured for generating a continuous multimodal representation of the probability distribution of a mask design in latent space 812, a second neural network block (conditional mapping sub-model 806) configured for selecting a variant 902 during training, and a third neural network block (generative structure 804) configured for determining a mask design 904 based on target design 900 (e.g., represented by a CTM in this example) and variant 902.

As described above (e.g., at operation 702 in FIG. 7), a continuous multimodal representation of a probability distribution of target design 900 is generated in at least a portion of latent space 812. In some embodiments, target design 900 is a target substrate design for a semiconductor wafer. In some embodiments, target design 900 comprises an intended wafer pattern, and/or intermediate data associated with the intended wafer pattern including continuous transmission mask (CTM) data, a CTM image, an intermediate mask design, and/or other target designs. Latent space 812 comprises a distribution of feature variants 910 that can be used to generate mask designs based on target design 900. A feature may comprise a shape or structure associated with a target and/or a reticle design for a semiconductor device, for example.

Variant 902 is selected from the continuous multimodal representation in latent space 812. Variant 902 comprises a latent space representation of one or more features to be used to determine mask design 904. Selecting variant 902 comprises selecting a mode from the multimodal representation of the probability distribution, and sampling the variant from the selected mode. In some embodiments, variant 902 comprises information content from an OPC domain and/or SRAF domain (OPC/SRAF data 920), or propagation of that information from the second neural network block (conditional mapping sub-model 806) to latent space 812, for example.

Mask design 904 is determined based on target design 900 and variant 902, and/or other information. In some embodiments, determined mask design 904 comprises an image. In some embodiments, determining mask design 904 based on target design 900 and variant 902 comprises (1) mapping target design 900, CTM data, and/or a CTM image to mask design 904, and/or (2) mapping target design 900 to CTM data and/or a CTM image. In some embodiments, 920 also changes to match 904. (So there may effectively be three options, for example: 1. 900=target, 920, 904=OPC/SRAF; 2. 900=CTM, 920, 904=OPC/SRAF; and 3. 900=target, 920, 904=CTM). In some embodiments, determining mask design 904 comprises determining sub resolution assist feature (SRAF) and/or optical proximity correction (OPC) data for mask design 904. In some embodiments, the SRAF data and the OPC data are determined as separate contributions.

FIG. 9 also illustrates mathematics associated with the operations described above. In FIG. 9, o represents OPC/SRAF data, c represents CTM data, s represents a posteriori mode selection probability, d represents a discrete categorical one-hot encoding and/or a categorical sample output of s, and ô represents inferred OPC/SRAF data. (In this example, h=conditional encoder model (as part of the conditional mapping sub-model), 1=latent variable, k=summation index, g=generative model (as part of the U-net), N=normal distribution (with mean=k/n and variance=1/n), and n=latent space dimension. In some embodiments, h=conditional encoder model, ˜ implies that the variable is distributed according to the given distribution, and the summation, since d is a 1-hot encoding is the selection of the variant. In addition, in the context of other terms used here, f=the first model or block, h=the second model or block, and g=the third model or block.)

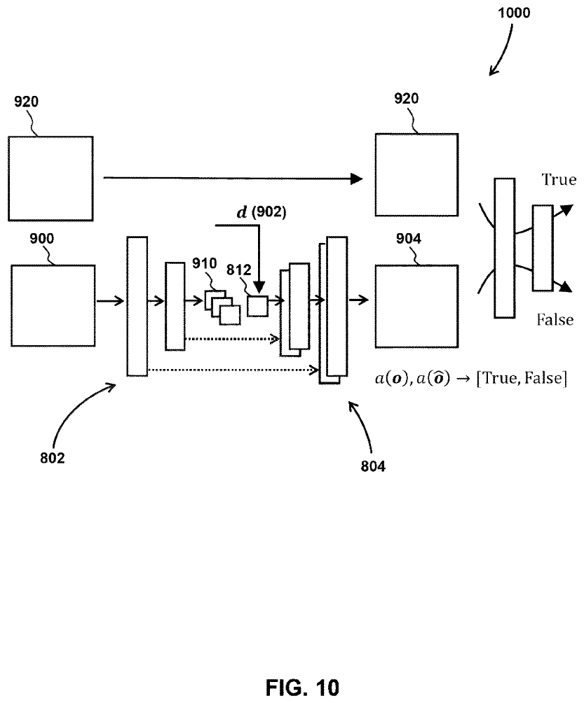

FIG. 10 illustrates an adversarial sub-model 1000 that may be included in and/or used to train model 800. As described above (see operation 708 in FIG. 7) model 800 can be trained by classifying output mask designs 904 as fake or genuine with adversarial training sub-model 1000 such that, after training, outputs are indistinguishable by the adversarial sub-model from real reference data (e.g., OPC/SRAF data 920 in this example). In this context, model 800 is tasked with fooling adversarial sub-model 1000 such that its outputs (e.g., 904) are classified as genuine. This is configured to ensure that the outputs from model 800 are indistinguishable from real reference data and do not include spurious features. Note that in this example, d (described above—also see selected variant 902) is a random selection (a 1-hot encoding).

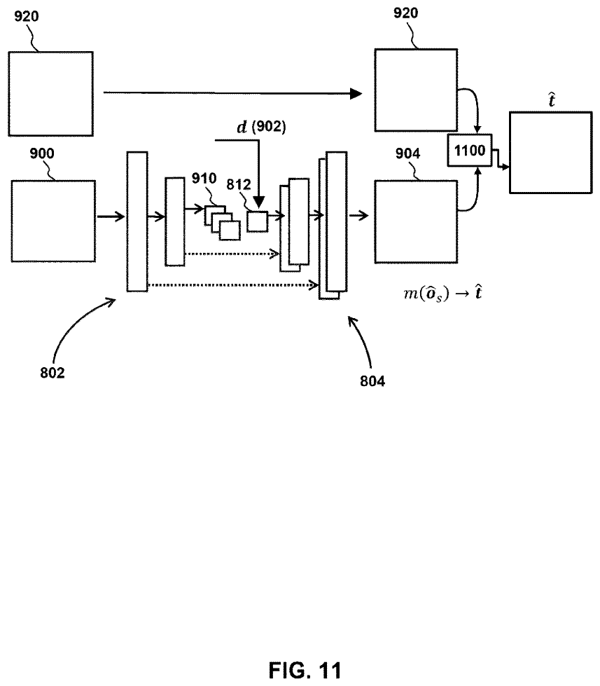

FIG. 11 illustrates a forward consistency sub-model 1100 that may be included in and/or used to train model 800. As described above (see operation 708 in FIG. 7), forward consistency sub-modelling may be performed to ensure a determined mask design 904 will create a desired semiconductor wafer structure that correspond to the target design. In some embodiments, the forward consistency sub-modelling is performed by a fixed physical model and/or a parametric model that approximates physics of a semiconductor manufacturing process.

Forward consistency sub-modelling is configured to ensure that inferred OPC/SRAF features, for example, are appropriate to create a desired pattern on a wafer. Forward consistency sub-model 1100 can be derived from the physical properties of the optical elements of a lithograph apparatus (e.g., as described above) and of resist (e.g., such that forward consistency sub-model 1100 is a fixed physical model). Alternatively, forward consistency sub-model 1100 may be a parametric model that approximates the physics of one or more manufacturing processes, with model parameters based on experimental and/or empirical data. Forward consistency sub-model 1100 may be pretrained (and/or constructed based on physics properties), for example. Forward consistency sub-model 1100 is configured to ensure that any choice of the sampling applied via d results in a valid mask design, i.e., if d is changed a similar target design approximation t is still output if the resulting ô=g(Σₖlₖ·dₖ) with f(c)→lₖ is passed through forward consistency sub-model 1100, with m(ô) remaining the same (where m is a forward consistency sub-model as described herein).

In addition to the sub-models described above, additional regularization/loss cost may be applied during training of model 800. As described above (operation 708 shown in FIG. 7) additional regularization/loss cost may be applied during the training of any of the neural network blocks of model 800 (FIG. 8, 9). Application of the regularization/loss cost comprises application of cost terms that penalize an amount of jagged edges in the determined mask design, reweighting of cost terms that penalize the amount of jagged edges, application of a cost term that places priority of binary pixel values in an image associated with the determined mask design, application of a fixed selection choice for a selection of a best mask design, and/or applying regularization on difference between two versions of the mask design. This can ensure that resulting inferred images output by model 800 have features with sharp edges and that approximate rectangles, for example. This can be achieved by placing penalty terms on the inferred image gradients, similar to total variation approaches. Additionally, a penalty may be added to second order image gradients (e.g., the cross term in the X-Y direction). This is configured to ensure that model 800 will prefer outcomes with a small number of corners/non jagged edges for output OPC/SRAF data.

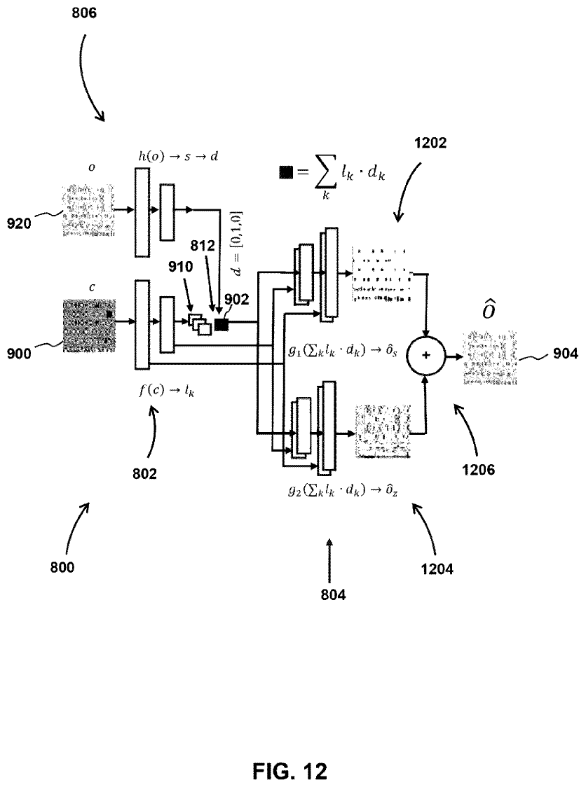

Note that the output OPC and SRAF data can be treated together or independently. By way of a non-limiting example, FIG. 12 shows an embodiment of model 800 where the OPC/SRAF contributions, 1202 and 1204 respectively, are treated separately, and then combined 1206 to generate mask design 904. From a regularization perspective once can make separate models for OPC and SRAF (they can have different requirements in terms of how rectangular they need to be, for example). However, another reason to split them is that perhaps they require different computational resolutions. An SRAF model, for example, (comprising only rectangles) can use a coarser pixel resolution compared to an OPC model, for example (which may have more complicated polygons with finer detail).

Training model 800 (including the first, second, and third neural network blocks described above and as shown in FIGS. 9 and 12) involves the use of training data generated using current approaches (described above). The first, second, and third neural network blocks are trained together by optimizing cost(s) in an adversarial fashion, e.g., by alternating between two sub-optimization tasks in a scheme similar to that from expectation-maximization approaches.

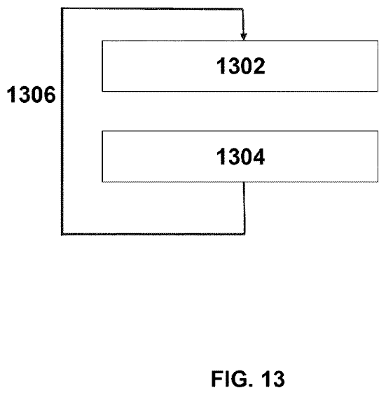

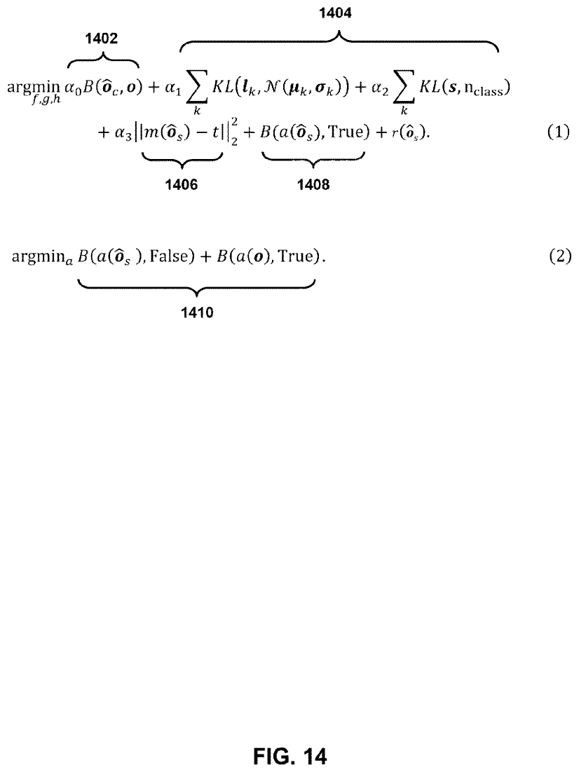

For example, FIG. 13 schematically illustrates iterations involved in finding joint solutions to the training optimization described above (as described above with respect to FIG. 7, various operations may be performed simultaneously, sequentially, iteratively, etc.). As shown in FIG. 13, a number of iterations of an optimization solver (e.g., a number of stochastic gradient descent steps) may be used (operation 1302) to partially solve a first optimization (keeping a (which represents an adversarial sub-model as described herein) and m (the forward consistency sub-model) of model 800 fixed); and a number (e.g., one or more) of stochastic gradient descent steps may be used (operation 1304) to partially solve a second optimization (keeping f, g, h, and m of model 800 fixed). The first and second optimizations are described by the equations in FIG. 14 described below. Operations 1302 and 1304 may be repeated 1306 until convergence and/or other stop criteria are met.

Training of model 800 (FIG. 8, 9, 12, etc.) is performed according to and/or based on Equations 1 and 2 shown in FIG. 14. As shown in FIG. 14, Equation (1) includes a fidelity term 1402 associated with reference OPC/SRAF features; variational terms 1404 configured to ensure than an appropriate (e.g., continuous multimodal) distribution is followed by the latent space (e.g., latent space 812 shown in FIGS. 8, 9, 12, etc.); a target match term 1406 where the function m is a known physical model (e.g., the forward sub-model described herein) configured to map a mask design to a target design; and an adversarial term 1408 configured to train model 800 to create outputs that fool the adversarial sub-model described above. Equation (2) includes discriminator training terms 1410 configured for classifying training or reference samples versus outputs generated by model 800.

In Equations (1) and (2), B stands for the binary cross entropy loss, e.g., between each pixel of a predicted OPC/SRAF image ô_{c} and the truth o; the mean μₖ and variance σₖ of the latent variables lₖ used in the variational prior, via the KL-divergence, are prescribed, for example k/n and 1/n, respectively; KL(s, n_{class}) represents the KL divergence with regards to a fixed n-class probability distribution, e.g., with equal probabilities for every class; the term r(ôₛ) denotes additional cost terms that can constrain, for a given choice of d, solution properties. Note that for simplicity only one latent element and a single vector d is described. For more latent elements the same procedure applies, with a selection applied per latent position. The symbol ô_{c} represents a conditional output of model 800, when d is generated based on a known sample o, and by ôₛ a sampled output of model 800, when d is generated randomly (d is random but still a 1-hot encoding) or using a specific choice that does not depend on the known sample o. This is an important distinction as o is only known during model training. During application of model 800, a predefined vector d is supplied that is configured to produce an appropriate mask design ôₛ, and as such model 800 is trained such that any sample d results in an appropriate target design.

Note that in FIGS. 9, 10, 11, 12 the blocks represent one latent element or a latent that has a single element. This is for the simplicity of making the figures, and adding more latent elements implies repeating the same scheme.

Extra regularization cost terms r(ôₛ)=ΣᵢTᵢ (ôₛ) are further described below. Note that not all of the options below need to be or should be applied at the same time, i.e., multiple parameters βᵢ can be set to 0. Similarly, multiple parameters αᵢ can also be set to zero for parts in the cost-function described herein. A first option for regularization cost terms comprises a cost terms that penalizes the amount of jagged edges in the resulting images ôₛ, given different samples d. Image gradients (dₓ, d_{y}: the difference between nearby pixels on x or y axis) or the second order cross term d_{xy} (dₓ applied on d_{y}) are used. A penalty is placed on the magnitude in an [symbol] -norm (note that other norms can be used) resulting in a cost:

$${T}_{1} ( {\hat{o}}_{s} ) = {β}_{1} \vert {d}_{x} ( {\hat{o}}_{s} ) \vert + {β}_{2} \vert {d}_{y} ( {\hat{o}}_{s} ) \vert + {β}_{3} \vert {d}_{x y} ( {\hat{o}}_{s} ) \vert . \qquad ( 3 )$$

The scales β act as a configuration parameter. To ensure that this is valid for every condition/choice of feature variant defined by the selection d, a penalty is applied for samples drawn from the possible distribution of the latent choices d. The dₓ, d_{y} terms are configured to ensure that the resulting mask designs are piecewise constant/flat while the d_{xy} term is configured to ensure that mask features have a small amount of corners.

A second option for regularization cost terms comprises a reweighting of the cost terms that penalizes an amount of jagged edges. Since a binary mask is sought, the cost can be reweighed such that it does not penalize values that are 0 or 1 (e.g., low gradients or very sharp gradients are sought). The cost term from Equation (4) below becomes non-convex. However, given the impact of the use of neural-network models (as described above), this does not pose a significant problem due to inherent non-convexity. The term T₂ describes such a cost:

$${T}_{2} ( {\hat{o}}_{s} ) = {β}_{4} \vert {d}_{x} ( {\hat{o}}_{s} ) \vert ( 1 - \vert {d}_{x} ( {\hat{o}}_{s} ) \vert ) + {β}_{5} \vert {d}_{y} ( {\hat{o}}_{s} ) \vert ( 1 - \vert {d}_{y} ( {\hat{o}}_{s} ) \vert ) + {β}_{6} \vert {d}_{x y} ( {\hat{o}}_{s} ) \vert ( 1 - \vert {d}_{x y} ( {\hat{o}}_{s} ) \vert ) . \qquad ( 4 )$$

Note that the domain of the mappings is [0, 1] so Equation (4) is well behaved. Well behaved may refer to terms in the cost-function being non-negative and bounded (by 1). The upper-bound by 1 is somewhat arbitrary, since any positive maximum value can be absorbed in the coefficients βᵢ. The output of the models can be restricted to be between 0 and 1, by using appropriate activation functions. As such (4) will only be evaluated for outputs belonging to this interval. If the model does not have these bounds, then the min of (4) lies at-infinity which is not the intended goal of T2. Effectively, T2 is used only if the model (third model) can only output values between 0 and 1. The same holds for Equation (3) above. Traditional iterative reweighting schemes can also be used.

A third option for regularization cost terms comprises a cost term that puts priority on having binary pixel values, values either 0 or 1 instead of any value in-between, resulting in

$${T}_{3} ( {\hat{o}}_{s} ) = {β}_{7} {\hat{o}}_{s} ( 1 - {\hat{o}}_{s} ) . \qquad ( 5 )$$

A fourth option for regularization cost terms comprises a fixed selection choice for the best selection, d_{best} is used for all targets such that the resulting cost:

$${T}_{4} ( {\hat{o}}_{s} ) = {β}_{8} \vert \vert m ( {\hat{o}}_{s} ) - t \vert {\vert}_{2}^{2} \qquad ( 6 )$$

is minimized. This allows a “best” or otherwise optimized outcome to be selected.

Alternatively, to reduce bias introduced by the regularization, regularization can be applied on the difference between two versions of masks designs, e.g., T₁ (ôₛ−ô_{c}), T₂ (ôₛ−ô_{c}) or T₃ (ôₛ−ô_{c}). This ensures that two possible mask designs associated with the same CTM (target design, for example) differ only by a small amount and the differences do not have many (jagged) edges.

There may be variations to the choice of cost used with some terms being dropped, or without including all of the described sub-models (e.g., not including the adversarial sub-model). Additionally, for simplicity of notation, the sampling procedure that is used to generate the output images ô is not explicitly described, though it is shown in FIGS. 9, 10, and 11 described above.

After training model 800 (shown in FIGS. 8, 9, 12, etc.), a mask design (e.g., including OPC/SRAF data) is determined (e.g., inference is performed) by supplying a predefined selection d, (e.g., a selection that was constrained to have the “best” performance in terms of a resulting target design via the forward sub-model m described above (e.g., sub-model 1100 in FIG. 11).

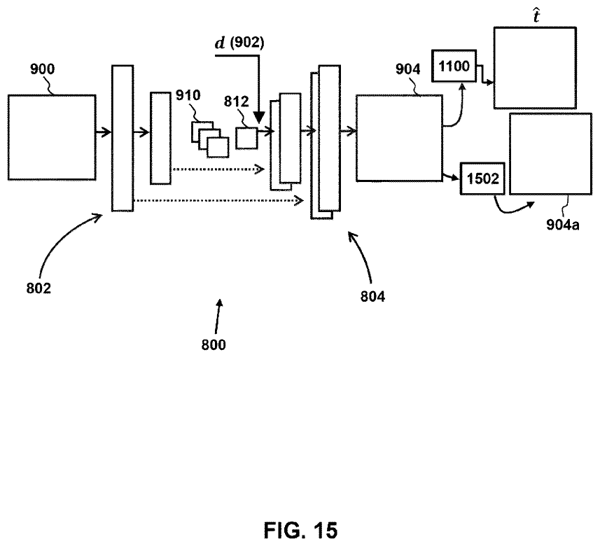

FIG. 15 illustrates an example of using a trained model 800 to infer (or otherwise determine) a mask design 904 (with OPC/SRAF features). In FIG. 15, the variant 902 selection d was determined during training to result in the “best” target image (among other possible variants that could have been selected). The resulting mask design 904 can be further processed 1502 via traditional methods (e.g., generating mask design 904a) to correct any possible small details that cannot be manufactured, for example. In some embodiments, sub-model 1100 can be used to evaluate performance, for example.

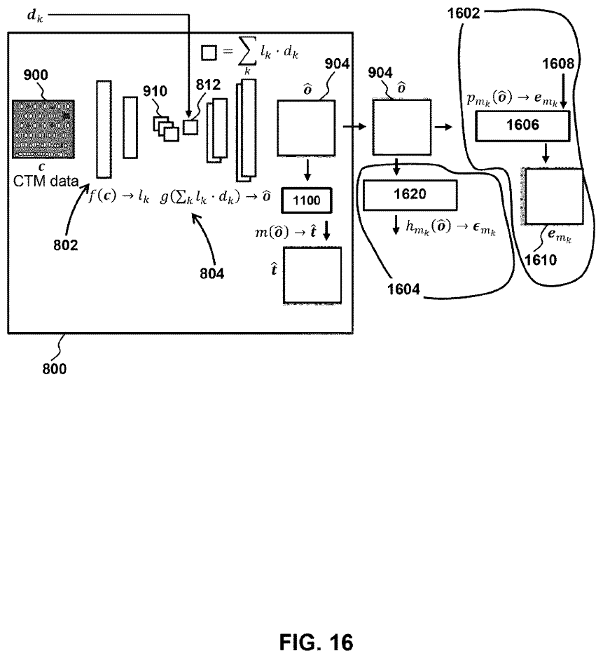

FIG. 16 provides a schematic view of model 800 shown in earlier figures reconfigured for training a fixed latent selection dₖ to achieve a target performance level with respect to predefined key performance indicators (KPIs) for a semiconductor manufacturing process. The term dₖ represents a variant selection associated with a key performance indicator k. Such a model can be used to quantify different perturbations in the manufacturing process to ensure that a mask prints valid target designs for a broad manufacturing process window. In some embodiments, model 800 may be trained for a target design (e.g., an input CTM image and/or data) and a fixed choice of selection dₖ, (e.g., selecting one of the middle elements for every latent position such that the fixed choice dₖ is optimal with regards to given process window perturbations).

FIG. 16 illustrates two different possible example options (option 1602 and option 1604) of model 800 reconfigured for training a fixed latent selection dₖ to achieve a target performance level with respect to predefined key performance indicators (KPIs) for a semiconductor manufacturing process. Option 1602 is associated with process window metrics. In option 1602, output mask design 904 (e.g., a resulting OPC/SRAF mask) is passed through a process window model 1606 that models a (random, pseudo-random or predefined) perturbation 1608 associated with process window variation. Perturbation 1608 can be a sample of a statistical mode for the physical changes that can occur during the manufacturing process, for example. The output of model 1606 is a target design 1610 determined based on process perturbation 1608 and input mask design 904. Model 1606 can, for example, be a forward model comprising a resist model perturbed to model small changes in the resist (other examples are contemplated). In some embodiments, a cost configured to bring the same performance in terms of a resulting target design over a range of perturbations may be added. Here e is a given resulting target given perturbation 1608. The present system is configured such that for any perturbation, e should be close to a designed desired target t, and as such this can be added a as a cost term during training. The symbol p represents a process window model. It may be similar to the forward consistency sub-model, but extended with additional process variation parameters, or other scanner perturbations like focus and dose variations, for example.

Option 1604 is associated with OPC/SRAF mask design properties. Option 1604 can be used to place penalty terms directly on OPC/SRAF features. One example of such penalty terms are the regularization options described above, that are configured to produce OPC/SRAF features that have (or have close to) rectangular shapes. The above described operations were for a random choice of d, while in option 1604 there is a specific determination as to a variant, via dₖ. This can be extended depending on what criteria are important for a mask design, (e.g., option 1604 may be configured to limit a number of features to reduce the cost of manufacturing the mask, add a cost for free-form OPC mask designed in place of the rectangular cost term, etc.). In option 1604, output mask design 904 (e.g., a resulting OPC/SRAF mask) is passed through a mask properties model 1620. The mask properties model h effectively translates these mask constraints into some (single or collection of) number(s). On these numbers the model puts a penalty in the cost during the training of the model, e.g., to ensure proximity to desired values.

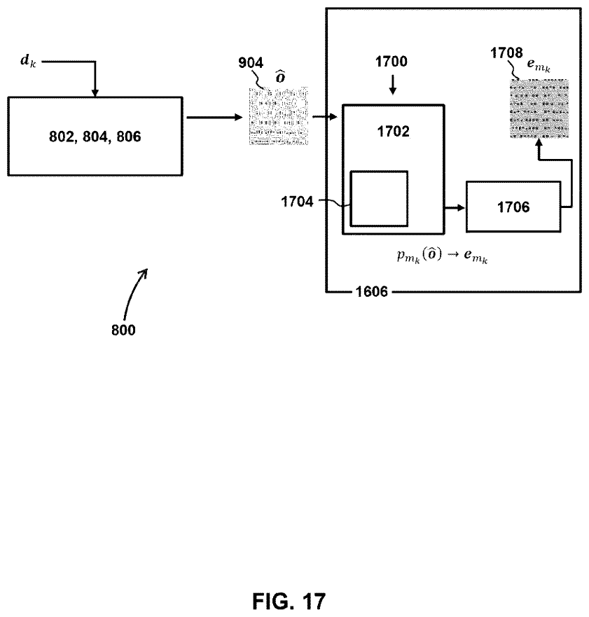

FIG. 17 illustrates an example embodiment of model 800 configured to account for or otherwise incorporate lithography scanner focus perturbations (e.g., using a process window model 1606 described above). FIG. 17 illustrates how the training cost options described above can be augmented with an additional term that encodes a target approximation quantity for a distribution of perturbations. This cost term can, for example, be the mean square error ∥eₘ_{ₖ}−t∥₂² between a perturbed target design eₘ_{ₖ} and a desired target design t. Note that during training samples may be drawn for the perturbation from a distribution of possible perturbations (shown by 1608), and as such model 800 is trained for optimality across the whole perturbation distribution, which is defined a priori. FIG. 17 shows sampling 1700 a distribution of focus perturbations that are possible in a scanner, a focus model 1702 for an aerial image 1704, a forward model 1706 associated with resist, and/or other models.

Note that adjustments to a semiconductor manufacturing process may be made based on the model outputs and/or other information. Adjustments may including changing one or more semiconductor manufacturing process parameters, for example. Adjustments may include pattern parameter changes (e.g., sizes, locations, and/or other design variables), and/or any adjustable parameter such as an adjustable parameter of the etching system, the source, the patterning device, the projection optics, dose, focus, etc. Parameters may be automatically or otherwise electronically adjusted by a processor (e.g., a computer controller), modulated manually by a user, or adjusted in other ways. In some embodiments, parameter adjustments may be determined (e.g., an amount a given parameter should be changed), and the parameters may be adjusted from prior parameter set points to new parameter set points, for example.

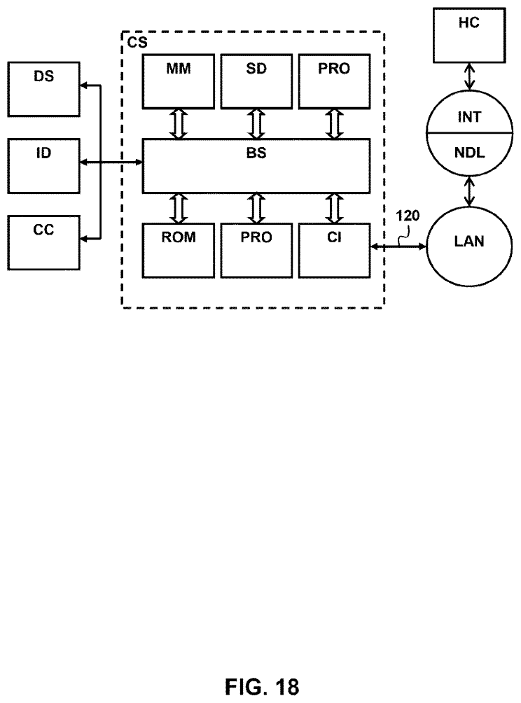

FIG. 18 is a diagram of an example computer system CS (which may be similar to or the same as CS shown in FIG. 3) that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have (machine-readable) instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more machine-readable instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, or stored in storage device SD, or other non-volatile storage for later execution. In this manner, computer system CS may obtain application code in the form of a carrier wave.

The concepts disclosed herein may be used with any imaging, etching, polishing, inspection, etc. system for sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiment of the present disclosure can be further described by the following clauses.

1. A method of determining a mask design, comprising:
generating a continuous multimodal representation of a probability distribution of a target design in at least a portion of a latent space, the latent space comprising a distribution of feature variants that can be used to generate mask designs based on the target design;
selecting a variant from the continuous multimodal representation in the latent space, the variant comprising a latent space representation of one or more features to be used to determine the mask design; and
determining the mask design based on the target design and the variant.
   2. The method of clause 1, wherein selecting the variant comprises selecting a mode from the multimodal representation of the probability distribution, and sampling the variant from the selected mode.
   3. The method of any of the previous clauses, wherein the generating, the selecting, and the determining are performed by an encoder structure and a generative structure with a conditional mapping sub-model.
   4. The method of clause 3, wherein the encoder structure and the generative structure form a U-net type deep learning model.
   5. The method of clause 4, wherein the U-net type deep learning model with the conditional mapping sub-model comprises a first neural network block configured for generating the continuous multimodal representation of the probability distribution of the target design in the portion of the latent space, a second neural network block configured for selecting the variant during training, and a third neural network block configured for determining the mask design based on the target design and the variant.
   6. The method of clause 5, wherein the first, second, and third neural network blocks are trained jointly.
   7. The method of clauses 5 or 6, wherein the second neural network block is trained to generate the distribution of feature variants that exist in input sub resolution assist feature (SRAF) and/or optical proximity correction (OPC) data.
   8. The method of clauses 6 or 7, wherein, during training, selected variants are used as ground truth to train the third neural network block to generate the mask design from an input target design and a mode selection choice given a selected variant.
   9. The method of clause 8, wherein the variant comprises information content from an OPC and/or SRAF domain, or propagation of that information from the second neural network block to the latent space.
   10. The method of clauses 5-9, further comprising training the first, second, and third neural network blocks by classifying output mask designs as fake or genuine with an adversarial training sub-model such that, after training, outputs from the third neural network block are indistinguishable by the adversarial sub-model from real reference data.
   11. The method of any of clauses 5-10, further comprising applying additional regularization/loss cost during the training of the first, second, and third neural network blocks.
   12. The method of clause 11, wherein application of the regularization/loss cost comprises application of cost terms that penalize an amount of jagged edges in the determined mask design, reweighting of cost terms that penalize the amount of jagged edges, application of a cost term that places priority of binary pixel values in an image associated with the determined mask design, application of a fixed selection choice for a selection of a best mask design, and/or applying regularization on difference between two versions of the mask design.
   13. The method of any of the previous clauses, wherein the target design comprises an intended wafer pattern, and/or intermediate data associated with the intended wafer pattern including continuous transmission mask (CTM) data, a CTM image, and/or an intermediate mask design.
   14. The method of clause 13, wherein determining the mask design based on the target design and the variant comprises (1) mapping the target design, the CTM data, and/or the CTM image to the mask design, and/or (2) mapping the target design to the CTM data and/or the CTM image.
   15. The method of any of the previous clauses, wherein the latent space models the distribution of feature variants that can be used to generate mask designs via variation Bayes inference techniques.
   16. The method of any of the previous clauses, wherein a feature comprises a shape or structure associated with a target and/or a reticle design for a semiconductor device.
   17. The method of any of the previous clauses, further comprising performing forward consistency sub-modelling configured to ensure the determined mask design will create a desired semiconductor wafer structures that correspond to the target design.
   18. The method of clause 17, wherein the forward consistency sub-modelling is performed by a fixed physical model and/or a parametric model that approximates physics of a semiconductor manufacturing process.
   19. The method of any of the previous clauses, wherein determining the mask design comprises determining sub resolution assist feature (SRAF) and/or optical proximity correction (OPC) data for the mask design.
   20. The method of clause 19, wherein the SRAF data and the OPC data are determined as separate contributions.
   21. The method of any of the previous clauses, wherein the target design is a target substrate design for a semiconductor wafer.
   22. The method of any of the previous clauses, wherein the determined mask design comprises an image.
   23. The method of any of the previous clauses, further comprising sampling a resulting conditional latent space by generating multiple selection options; and evaluating process window key performance indicators for resulting mask designs such that a most robust mask that a pretrained model can produce is determined.
   24. The method of any of the previous clauses, further comprising constructing an optimization problem and evaluating process window key performance indicators for resulting mask designs based on output from the optimization problem such that a most robust mask that a pretrained model can produce is determined.
   25. The method of any of the previous clauses, further comprising fixing a given latent parametrization and training the model to optimize for various process window key performance indicators given perturbations of a process window.
   26. A non-transitory computer readable medium having instructions thereon, the instructions when executed by a computer causing the computer to perform the method of any of clauses 1-23.
   27. A method of determining a semiconductor mask design with a model that learns a multimodal distribution of mask features, and selects variants that result in valid semiconductor wafer imaging, the method comprising:
generating, with a first neural network block of the model, a continuous multimodal representation of a probability distribution of a wafer target design in at least a portion of a latent space, the latent space comprising a distribution of feature variants that can be used to generate mask designs based on the target design;
selecting, with a second neural network block of the model and during training of the model, a variant from the continuous multimodal representation in the latent space, the variant comprising a latent space representation of one or more features to be used to determine the mask design, wherein the selecting comprises selecting a mode from the multimodal representation of the probability distribution, and sampling the variant from the selected mode; and
determining, with a third neural network block of the model, the mask design based on the target design and the variant,
wherein the model is a U-net type deep learning model with a conditional mapping sub-model.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A non-transitory computer readable medium having instructions thereon or therein, the instructions, when executed by a computer system, configured to cause the computer system to at least:
generate a continuous multimodal representation of a probability distribution of a target design in at least a portion of a latent space, the latent space comprising a distribution of feature variants that can be used to generate mask designs based on the target design;
select a variant from the continuous multimodal representation in the latent space, the variant comprising a latent space representation of one or more features to be used to determine the mask design; and
determine the mask design based on the target design and the variant.

2. The medium of claim 1, wherein the instructions configured to cause the computer system to select the variant are further configured to cause the computer system to select a mode from the multimodal representation of the probability distribution, and sample the variant from the selected mode.

3. The medium of claim 1, wherein the generation of the continuous multimodal representation, the selection of the variant, and the determination of the mask design are performed by an encoder structure and a generative structure with a conditional mapping sub-model.

4. The medium of claim 3, wherein the encoder structure and the generative structure form a deep learning model, wherein the deep learning model with the conditional mapping sub-model comprises a first neural network block configured for generating the continuous multimodal representation of the probability distribution of the target design in the portion of the latent space, a second neural network block configured for selecting the variant during training, and a third neural network block configured for determining the mask design based on the target design and the variant.

5. The medium of claim 4, wherein the first, second, and third neural network blocks are trained jointly, and wherein the second neural network block is trained to generate the distribution of feature variants that exist in input sub resolution assist feature (SRAF) and/or optical proximity correction (OPC) data.

6. The medium of claim 4, wherein selected variants are used as ground truth to train the third neural network block to generate the mask design from an input target design and a mode selection choice given a selected variant.

7. The method of claim 6, wherein the variant comprises information content from an optical proximity correction (OPC) and/or sub resolution assist feature (SRAF) domain, or propagation of that information from the second neural network block to the latent space.

8. The medium of claim 5, wherein the instructions are further configured to cause the computer system to train the first, second, and third neural network blocks by classifying output mask designs as fake or genuine with an adversarial training sub-model such that, after training, outputs from the third neural network block are indistinguishable by the adversarial sub-model from real reference data.

9. The medium of claim 5, wherein the instructions are further configured to cause the computer system to apply additional regularization/loss cost during the training of the first, second, and third neural network blocks, wherein application of the regularization/loss cost comprises application of cost terms that penalize an amount of jagged edges in the determined mask design, reweighting of cost terms that penalize the amount of jagged edges, application of a cost term that places priority of binary pixel values in an image associated with the determined mask design, application of a fixed selection choice for a selection of a best mask design, and/or apply regularization on a difference between two versions of the mask design.

10. The medium of claim 1, wherein the target design comprises an intended wafer pattern, and/or intermediate data associated with the intended wafer pattern including continuous transmission mask (CTM) data, a CTM image, and/or an intermediate mask design, and wherein the instructions configured to cause the computer system to determine the mask design based on the target design and the variant are further configured to cause the computer system to (1) map the target design, the CTM data, and/or the CTM image to the mask design, and/or (2) map the target design to the CTM data and/or the CTM image.

11. The medium of claim 1, wherein the instructions are further configured to cause the computer system to perform forward consistency sub-modelling configured to ensure the determined mask design will create a desired semiconductor wafer structure that corresponds to the target design, wherein the forward consistency sub-modelling is performed by a fixed physical model and/or a parametric model that approximates physics of a semiconductor manufacturing process.

12. The medium of claim 1, wherein the instructions configured to cause the computer system to determine the mask design are further configured to cause the computer system to determine sub resolution assist feature (SRAF) and/or optical proximity correction (OPC) data for the mask design, and wherein the SRAF data and the OPC data are determined as separate contributions.

13. The medium of claim 1, wherein the instructions are further configured to cause the computer system to sample a resulting conditional latent space by generating multiple selection options; and evaluate process window key performance indicators for resulting mask designs such that a most robust mask that a pretrained model can produce is determined.

14. The medium of claim 1, wherein the instructions are further configured to cause the computer system to construct an optimization problem and evaluate process window key performance indicators for resulting mask designs based on output from the optimization problem such that a most robust mask that a pretrained model can produce is determined.

15. The medium of claim 1, wherein the instructions are further configured to cause the computer system to fix a given latent parametrization and train the model to optimize for various process window key performance indicators given perturbations of a process window.

16. A method of determining a mask design, the method comprising:
generating a continuous multimodal representation of a probability distribution of a target design in at least a portion of a latent space, the latent space comprising a distribution of feature variants that can be used to generate mask designs based on the target design;
selecting a variant from the continuous multimodal representation in the latent space, the variant comprising a latent space representation of one or more features to be used to determine the mask design; and
determining, by a hardware computer system, the mask design based on the target design and the variant.

17. The method of claim 16, wherein the selecting the variant comprises selecting a mode from the multimodal representation of the probability distribution, and sampling the variant from the selected mode.

18. The method of claim 16, wherein the generating, the selecting, and the determining are performed by an encoder structure and a generative structure with a conditional mapping sub-model.

19. The method of claim 16, wherein the target design comprises an intended wafer pattern, and/or intermediate data associated with the intended wafer pattern including continuous transmission mask (CTM) data, a CTM image, and/or an intermediate mask design, and wherein determining the mask design based on the target design and the variant comprises (1) mapping the target design, the CTM data, and/or the CTM image to the mask design, and/or (2) mapping the target design to the CTM data and/or the CTM image.

20. A non-transitory computer readable medium having instructions thereon or therein, the instructions, when executed by a computer system, configured to cause the computer system to at least:
generate, with a first neural network block of the model, a continuous multimodal representation of a probability distribution of a target design in at least a portion of a latent space, the latent space comprising a distribution of feature variants that can be used to generate mask designs based on the target design;
select, with a second neural network block of the model, a variant from the continuous multimodal representation in the latent space, the variant comprising a latent space representation of one or more features to be used to determine a mask design, wherein the selection comprises selection of a mode from the multimodal representation of the probability distribution, and sampling of the variant from the selected mode; and
determine, with a third neural network block of the model, the mask design based on the target design and the variant,
wherein the model is a U-net type deep learning model with a conditional mapping sub-model.
